(19) United States
(12) Patent Application Publication
(10) Pub. No.: US 2026/0257547 A1
(43) Pub. Date: Sep. 3, 2026

(54) Construction Machine

(71) Applicant: Putzmeister Engineering GmbH, Aichtal (DE)

(72) Inventor: Christian ZIEMENS, Stuttgart (DE)

(21) Appl. No.: 18/881,862

(22) PCT Filed: Jul. 3, 2023
(86) PCT No.: PCT/EP2023/068174

§ 371 Date: Jan. 7, 2025

(30) Foreign Application Priority Data
Jul. 8, 2022 (DE) 10 2022 207 009.7

(51) Int. Cl. B60K 1/00; B60L 58/26; E04G 21/02; F15B 21/0423; H05K 7/20

(52) U.S. Cl. CPC B60K 1/00; B60L 58/26; E04G 21/02; F15B 21/0423; H05K 7/20927; B60K 2001/005; B60K 2001/006; B60L 2200/40; B60L 2240/545

(57) ABSTRACT

A construction machine includes: a battery; at least one electric drive which is supplied by the battery; a hydraulic circuit in which hydraulic oil circulates; at least one hydraulic drive which is supplied by the hydraulic circuit, and a first coolant circuit for cooling the battery and the hydraulic oil, wherein a portion of the hydraulic oil circulates in the first coolant circuit as coolant.

### BACKGROUND AND SUMMARY

The invention is based on the object of providing a construction machine comprising components which are to be cooled and whereof the cooling concept is as efficient as possible.

The construction machine comprises a rechargeable battery and at least one electric drive having at least one electric motor, which is supplied by the battery. The battery may be arranged, for example, in the construction machine.

The construction machine furthermore comprises a hydraulic circuit in which hydraulic oil circulates.

The construction machine furthermore comprises at least one hydraulic drive, which is supplied by the hydraulic circuit. In this regard, reference should be made, for example, to WO 2013/045167 A2 by the Applicant, which demonstrates such hydraulic circuits and associated hydraulic drives.

The construction machine furthermore comprises a first cooling circuit for cooling the battery and the hydraulic oil, wherein at least a portion of hydraulic oil circulates in the first cooling circuit as coolant. The portion of hydraulic oil which serves as coolant may be obtained, for example, at a suction return filter, as disclosed in WO 2013/045167 A2.

In one embodiment, the first cooling circuit comprises: a hydraulic oil pump for generating an adjustable volume flow of the portion of hydraulic oil, a first cooler, which has an adjustable cooling capacity and through which the portion of hydraulic oil flows, and a first heat exchanger, which is connected downstream of the first cooler, is thermally coupled to the battery and through which the portion of hydraulic oil flows. The cooling capacity of the first cooler may be adjusted, for example, by means of a fan, which generates an adjustable cooling air flow by means of a variable fan speed. The first cooler may also be designed, for example, as a heat pump. The first cooler may be arranged, for example, in/on a supporting leg of a self-driving concrete pump.

In one embodiment, the construction machine furthermore comprises: a battery temperature controller, which is designed to control a battery temperature according to a predeterminable setpoint value, wherein a correcting variable of the battery temperature controller is a cooling capacity of the first cooler. The predeterminable setpoint value of the battery temperature may be, for example, in the room-temperature range.

In one embodiment, the construction machine furthermore comprises: a hydraulic oil temperature controller, which is designed to control a hydraulic oil temperature according to a predeterminable setpoint value, wherein a correcting variable of the hydraulic oil temperature controller is a volume flow of the portion of hydraulic oil. The predeterminable setpoint value of the hydraulic oil temperature may be, for example, in a range between 30° Celsius and 60° Celsius.

In one embodiment, the hydraulic oil temperature controller is parameterized to be slower than the battery temperature controller in order to avoid oscillations of the coupled control circuits where possible.

In one embodiment, the at least one electric drive, for example in the form of an electric motor, is likewise cooled by means of the first cooling circuit.

In one embodiment, the construction machine comprises power electronics, for example in the form of a frequency converter, for activating the at least one electric drive, wherein the power electronics are likewise cooled by means of the hydraulic oil.

In one embodiment, the first cooling circuit comprises: a second cooler, through which the portion of hydraulic oil flows, and a second heat exchanger, which is connected downstream of the second cooler, is thermally coupled to the power electronics and through which the portion of hydraulic oil flows.

In one embodiment, the construction machine comprises a second cooling circuit for cooling the power electronics, wherein a further portion of hydraulic oil circulates in the second cooling circuit as coolant.

In one embodiment, the first cooling circuit comprises a bypass valve, which, in a bypass switching position, guides the portion of hydraulic oil past the first heat exchanger and which, in a cooling switching position, conducts the portion of hydraulic oil through the first heat exchanger. The bypass switching position may then be brought about, for example, by the battery temperature controller if cooling of the battery is not required. Accordingly, the cooling switching position may then be brought about by the battery temperature controller if cooling of the battery is required.

In one embodiment, the construction machine is a concrete pump.

The invention is described in detail below with reference to the drawings.

### BRIEF DESCRIPTION OF THE DRAWINGS

FIG. 1 shows, in highly schematic form, a construction machine having a first cooling circuit for hydraulic and electric drives according to a first embodiment of the invention;

FIG. 2 shows, in highly schematic form, a construction machine according to a further embodiment; and

FIG. 3 shows, in highly schematic form, a construction machine according to a further embodiment.

### DETAILED DESCRIPTION OF THE DRAWINGS

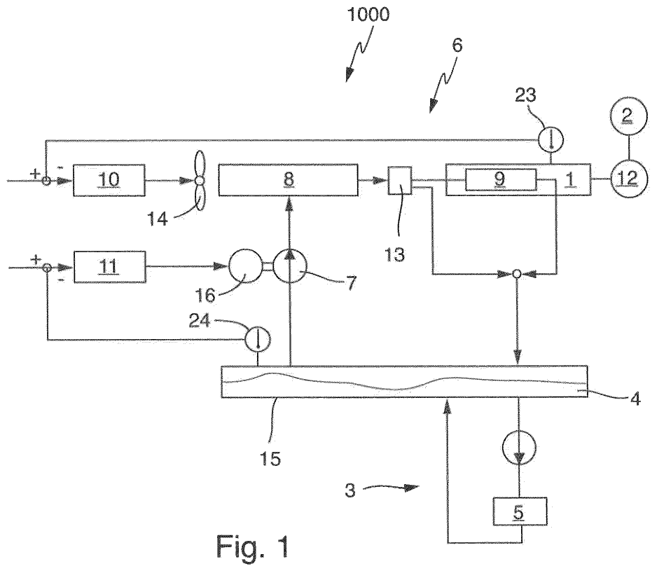

FIG. 1 shows, in highly schematic form, a construction machine 1000 in the form of an (auto) concrete pump, comprising a rechargeable battery 1, an electric drive 2, which is supplied by the battery 1, a hydraulic circuit 3, in which hydraulic oil 4 circulates, a hydraulic drive 5, which is supplied by the hydraulic circuit 3, and a first cooling circuit 6 for cooling the battery 1 and the hydraulic oil 4, wherein a portion of hydraulic oil 4 circulates in the first cooling circuit 6 as coolant. Besides hydraulic oil 4, no further or other coolant is used.

The first cooling circuit 6 comprises a hydraulic oil pump 7 for generating an adjustable volume flow of the portion of hydraulic oil 4. By way of example, the hydraulic oil pump 7 is a constant pump, which, to generate the adjustable volume flow, is driven by means of an electric motor 16 with an adjustable speed. The speed of the electric motor 16 is the correcting variable of the hydraulic oil temperature controller 11.

The first cooling circuit 6 furthermore comprises a first cooler 8 having an associated fan 14 with an adjustable cooling capacity, wherein the portion of hydraulic oil 4 flows through the first cooler 8. The cooling capacity may be adjusted, for example, by adjusting a fan speed.

The first cooling circuit 6 furthermore comprises a first heat exchanger 9, which is connected downstream of the first cooler 8, is thermally coupled to the battery 1 and through which the portion of hydraulic oil 4 flows.

The construction machine 1000 comprises a battery temperature controller 10, which is designed to control a battery temperature, measured by means of a temperature sensor 23, according to a predeterminable setpoint value, wherein a correcting variable of the battery temperature controller 10 is the cooling capacity of the first cooler 8.

The construction machine 1000 furthermore comprises a hydraulic oil temperature controller 11, which is designed to control a hydraulic oil temperature, measured by means of a temperature sensor 24, according to a predeterminable setpoint value, wherein a correcting variable of the hydraulic oil temperature controller 11 is a volume flow of the portion of hydraulic oil 4. The hydraulic oil temperature controller 11 is parameterized to be slower than the battery temperature controller 10, for example through appropriate selection of controller time constants, etc.

The electric drive 2 is likewise cooled by means of the first cooling circuit 6, in that, for example, a heat exchanger (not illustrated) is thermally coupled to the electric drive 2, wherein the portion of hydraulic oil likewise flows through this heat exchanger.

The construction machine furthermore comprises power electronics 12 for activating the electric drive 2.

The first cooling circuit 6 comprises a bypass valve 13, which, in a bypass switching position, guides the portion of hydraulic oil 4 past the first heat exchanger 9 and which, in a cooling switching position, conducts the portion of hydraulic oil 4 through the first heat exchanger 9.

In the bypass switching position of the bypass valve 13, in the simplest case, the battery temperature controller 10 may be deactivated. In this case, the cooling capacity of the first cooler 8 may be set, for example, to such a fixed value that is sufficient for cooling the hydraulic oil. It is furthermore contemplated that, in this case, the hydraulic oil temperature controller 11 influences the cooling capacity of the first cooler 8 as a further correcting variable.

By means of the invention, it is possible to cool both the battery 1 of an electrically driven machine 2, in particular an electrified concrete pump, and also the hydraulic oil 4. The cooling system is designed as a common circuit, in particular to reduce the complexity of the mechanical system.

A defined hydraulic oil volume flow is conveyed from the hydraulic circuit 3 or a hydraulic oil tank 15 through the first (hydraulic oil) cooler 8 by means of the hydraulic oil pump 7. The first cooler 8 cools the hydraulic oil 4 to a temperature which is sufficiently below the desired battery temperature. The cooled hydraulic oil 4 is subsequently conducted through the battery 1 and cools the latter. The hydraulic oil flow is subsequently conducted back into the hydraulic system, for example into the tank 15, and cools the hydraulic oil 4 since the target battery temperature is significantly lower than that of the hydraulic system.

The control of the temperature levels of the battery 1 and hydraulic oil 4 takes place, for example, via two control circuits. The cooling of the battery 1 takes place via a first control circuit. The battery temperature is measured and compared with the setpoint temperature. If the temperature is too high or too low, the cooling capacity of the first cooler 8 is adapted accordingly, for example, via the speed of the fan 14.

The cooling of the hydraulic oil 4 takes place via a second control circuit. The temperature of the hydraulic oil 4 in the system/tank 15 is measured and compared with the setpoint temperature. If the temperature is too high or too low, the cooling volume flow is adapted accordingly.

Since the hydraulic oil 4 at the output of the battery 1 has a virtually constant temperature owing to the battery control, the quantity of cooled oil which flows back into the hydraulic system is controlled via the volume flow of the portion of hydraulic oil. The adapting to the volume flow may take place, for example, by means of a variable displacement pump with a constant speed or, as illustrated, by means of a constant pump with a variable speed.

Since the control circuits are coupled to one another via the volume flow, it is useful to adapt the control circuits to one another. One variant involves configuring the hydraulic oil temperature control to be slower than that of the battery temperature control, for example to avoid oscillations. As a variant, the system as a whole may also be equipped with an integrated control arrangement, in which the two temperatures plus setpoint variables serve as input variables and the volume flow and the cooling capacity serve as output variables.

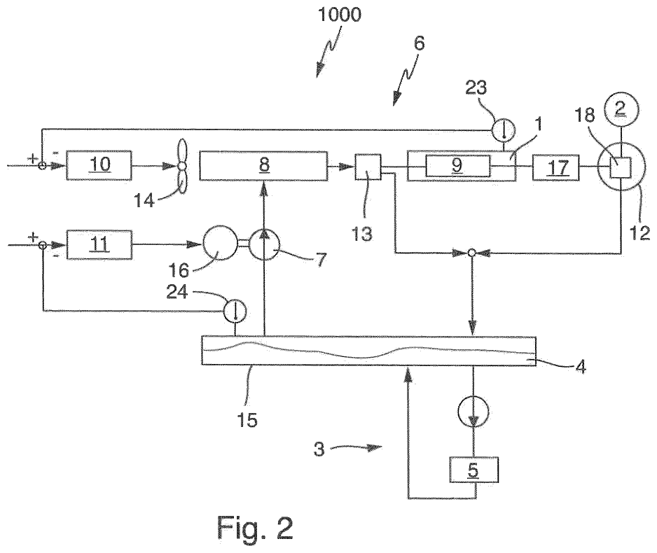

FIG. 2 shows, in highly schematic form, a construction machine 1000 according to a further embodiment. If needed, the first cooling circuit 6 here additionally comprises a second cooler 17, through which the portion of hydraulic oil 4 flows. The first cooling circuit 6 furthermore comprises a second heat exchanger 18, which is connected downstream of the second cooler 17, is thermally coupled to the power electronics 12 and through which the portion of hydraulic oil 4 flows in order to cool the power electronics 12. The second cooler 17 may have an adjustable cooling capacity. Furthermore, a temperature controller (not illustrated) may be provided, which controls a temperature of the hydraulic oil 4 flowing out of the second cooler 17 according to a setpoint value.

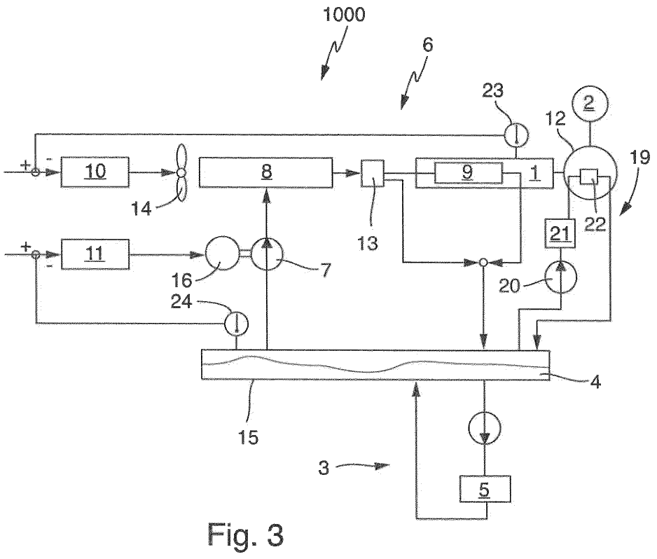

FIG. 3 shows, in highly schematic form, a construction machine 1000 according to a further embodiment. The construction machine 1000 comprises a second cooling circuit 19 for cooling the power electronics 12, wherein a further portion of hydraulic oil 4 circulates in the second cooling circuit 19 as coolant. The second cooling circuit 19 comprises a further hydraulic oil pump 20, a third cooler 21 and a second heat exchanger 22, which is connected downstream, is thermally coupled to the power electronics 12 and through which the further portion of hydraulic oil 4 flows. A temperature of the power electronics 12 may be controlled, for example, by means of an associated temperature controller, which uses, for example, a delivery rate of the further hydraulic oil pump 20 and/or a cooling capacity of the third cooler 21 as a correcting variable.

By means of the invention, the number of physical components required for the cooling operation may be reduced, since a separate first cooling circuit for the battery is omitted. A simpler physical system design is furthermore realized. Furthermore, additional cooling medium is not required since, overall, only hydraulic oil is used.

1. A construction machine comprising:
a battery,
at least one electric drive, which is supplied by the battery,
a hydraulic circuit in which hydraulic oil circulates,
at least one hydraulic drive, which is supplied by the hydraulic circuit, and
a first cooling circuit for cooling the battery and the hydraulic oil, wherein a portion of hydraulic oil circulates in the first cooling circuit as coolant.

2. The construction machine as claimed in claim 1, wherein
the first cooling circuit comprises:
a hydraulic oil pump for generating an adjustable volume flow of the portion of hydraulic oil,
a first cooler, which has an adjustable cooling capacity and through which the portion of hydraulic oil flows, and
a first heat exchanger, which is connected downstream of the first cooler, is thermally coupled to the battery and through which the portion of hydraulic oil flows.

3. The construction machine as claimed in claim 1, further comprising:
a battery temperature controller, which is designed to control a battery temperature according to a predeterminable setpoint value, wherein a correcting variable of the battery temperature controller is a cooling capacity of the first cooler.

4. The construction machine as claimed in claim 3, further comprising:
a hydraulic oil temperature controller, which is designed to control a hydraulic oil temperature according to a predeterminable setpoint value, wherein a correcting variable of the hydraulic oil temperature controller is a volume flow of the portion of hydraulic oil.

5. The construction machine as claimed in claim 4, wherein
the hydraulic oil temperature controller is parameterized to be slower than the battery temperature controller.

6. The construction machine as claimed in claim 1, wherein
the at least one electric drive is cooled via the first cooling circuit.

7. The construction machine as claimed in claim 1, further comprising:
power electronics for activating the at least one electric drive, wherein the power electronics are cooled via the hydraulic oil.

8. The construction machine as claimed in claim 7, wherein
the first cooling circuit comprises:
a second cooler, through which the portion of hydraulic oil flows, and
a second heat exchanger, which is connected downstream of the second cooler, is thermally coupled to the power electronics and through which the portion of hydraulic oil flows.

9. The construction machine as claimed in claim 7, further comprising:
a second cooling circuit for cooling the power electronics, wherein a further portion of hydraulic oil circulates in the second cooling circuit as coolant.

10. The construction machine as claimed in one of claim 2, wherein
the first cooling circuit comprises a bypass valve, which, in a bypass switching position, guides the portion of hydraulic oil past the first heat exchanger and which, in a cooling switching position, conducts the portion of hydraulic oil through the first heat exchanger.

11. The construction machine as claimed in claim 1, wherein
the construction machine is a concrete pump.
